(19) United States
(12) Patent Application Publication
(10) Pub. No.: US 2004/0041716 A1
(43) Pub. Date: Mar. 4, 2004

(54) Virtual keyboard and keyboard support arm assembly

(75) Inventor: Peter M. Barber, Fergus (CA)

Correspondence Address: BANNER & WITCOFF, LTD., TEN SOUTH WACKER DRIVE, SUITE 3000, CHICAGO, IL, 60606, US

(73) Assignee: CompX International Inc., Mauldin, SC

(21) Appl. No.: 10/230,577

(22) Filed: Aug. 29, 2002

(51) Int. Cl. H03M 11/00; H03K 17/94

(52) U.S. Cl. 341/22; 345/168

(57) ABSTRACT

A keyboard support arm assembly includes the keyboard platform having a planar surface and upon which is projected a virtual keyboard the projection being by means of a projection device having virtual image capability and having the capability of reading on a site-by-site basis the position and existence of or status of any manual digit input signal.

### BACKGROUND OF THE INVENTION

In a principal aspect, the present invention relates to an integral virtual keyboard and keyboard support arm assembly.

With the advent of the computer and the personal computer, installation of a keyboard support arm in an office or other environments has become commonplace. Typically a keyboard support arm includes a keyboard support platform mounted on an adjustable bracket which is, in turn, pivotally attached to one or more arms that are linked to the underside of a desk surface. Various linkages and features of such combinations are disclosed in prior art references including the following:

| U.S. Pat. No. | Title | Issue Date |
|---|---|---|
| 4,616,798 | Adjustable support for CRT | Oct. 14, 1986 |
| | Keyboard | |
| 4,632,349 | Support Assembly | Dec. 30, 1986 |
| 4,790,611 | Adjustable Work Surface | Dec. 13, 1988 |
| 4,826,123 | Adjustable Keyboard Support | May 2, 1989 |
| 4,843,978 | Table with Vertically | Jul. 4, 1989 |
| | Adjustable Work Surface | |
| 4,988,066 | Selectively Controlled | Jan. 29, 1991 |
| | Keyboard Support | |
| 5,037,054 | Adjustable Support | Aug. 6, 1991 |
| | Mechanism for a Keyboard | |
| | Platform | |
| 5,145,136 | Adjustable Support | Sep. 8, 1992 |
| | Mechanism for a Keyboard | |
| | Platform | |
| 5,257,767 | Adjustable Support | Nov. 2, 1993 |
| | Mechanism for a Keyboard | |
| | Platform | |

Such prior art references are incorporated herewith.

Typically with respect to such devices, a personal computer or a keyboard is placed on a surface platform. The platform is then adjusted to the right level, pitch, yaw and extent of separation from the desk support for the particular operator. Also, typically, a brake mechanism is utilized to lock the keyboard support platform in a specific, desired orientation or position. Additionally, various mechanisms have been devised to release the platform from a locked position and to permit the ease of adjustment and storage of the platform when not in use.

In all instances, the platform is configured and positioned in a manner which will support a keyboard or a personal computer. The keyboard or personal computer will have a fixed weight which requires that the platform be manufactured in a manner which will support such a weight. Additionally, the platform must be made in a manner which enables the use of ancillary elements or features such as a mouse and incorporation of ergonomic features such as wrist support pads.

There has remained, however, the necessity to provide a keyboard support platform and assembly which combines with projected images and apparatus which projects such images, but which is capable of adjustment to a level, yaw, pitch and separation from a support surface without distortion of the project image.

### SUMMARY OF THE INVENTION

Briefly, the present invention comprises the combination of a keyboard support arm assembly and a virtual projection monitor which is mounted on the top edge of the keyboard support platform of the assembly in a manner that enables undistorted projection of a virtual, keyboard image onto a flat, planar projection surface of the platform and so that the image is properly positioned for engagement of site specific elements thereof by an operator or typist. Additionally, the keyboard support arm assembly includes an arrangement of ergonomic pads which to facilitate utilization of the support platform, and more particularly, in combination with a virtual keyboard image projected thereon.

Thus, it is an object of the invention to provide an improved keyboard support arm assembly.

It is a further object of the invention to provide a keyboard support arm assembly which is combined with apparatus for projecting a virtual keyboard image onto a projection surface of the keyboard platform associated with the keyboard support art assembly.

It is a further object of the invention to provide a keyboard support arm assembly which permits adjustment of the keyboard support platform in any one of a number of independent ways including adjustment of the pitch, yaw, and level of the platform and the extent of spacing of the platform from the desk support associated with the platform.

Further, the support arm assembly desirably includes and it is an object thereof to include means for adjustment of the support arm assembly and for support of the parts utilized to implement usage of the virtual image on the keyboard support platform.

These and other objects, advantages and features of the invention will be set forth in the detailed description which follows.

### BRIEF DESCRIPTION OF THE DRAWING

In the detailed description which follows, reference will be made to the drawing comprised of the following figures:

FIG. 1 is a plan view of a first embodiment of the combination of the invention;

FIG. 2 is an isometric view of the embodiment of FIG. 1;

FIG. 3 is a side elevation of the embodiment of FIG. 1 wherein the keyboard arm and the virtual projection monitor are in an operating position; and

FIG. 4 is a side elevation of the embodiment of FIG. 1 in the storage position.

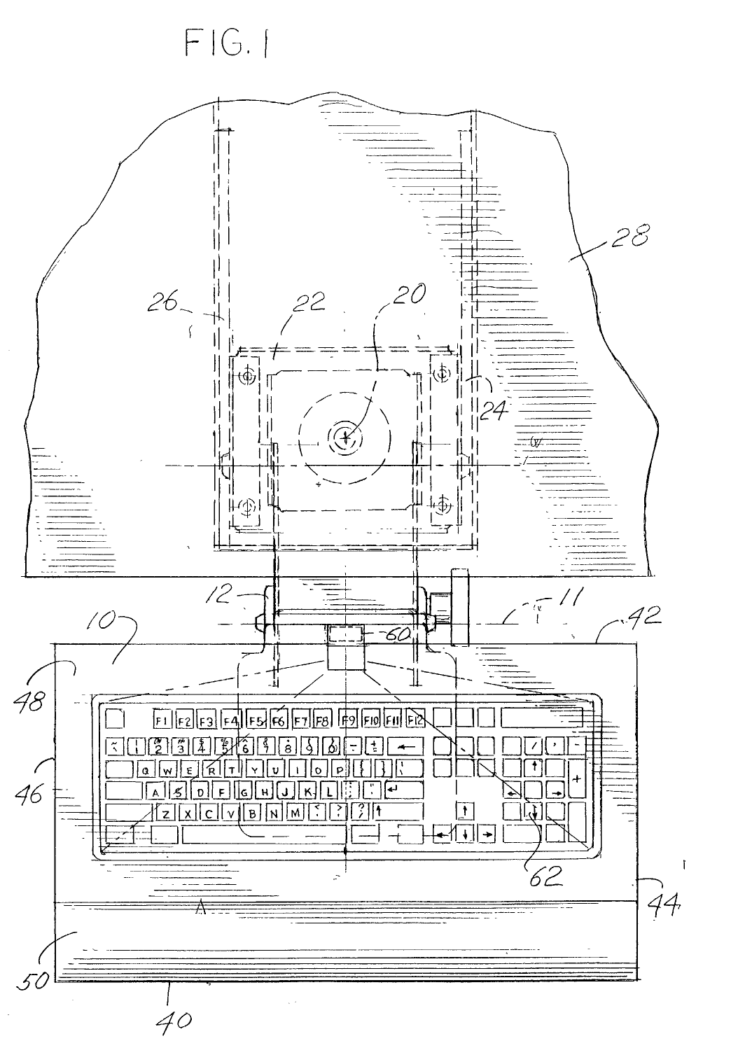

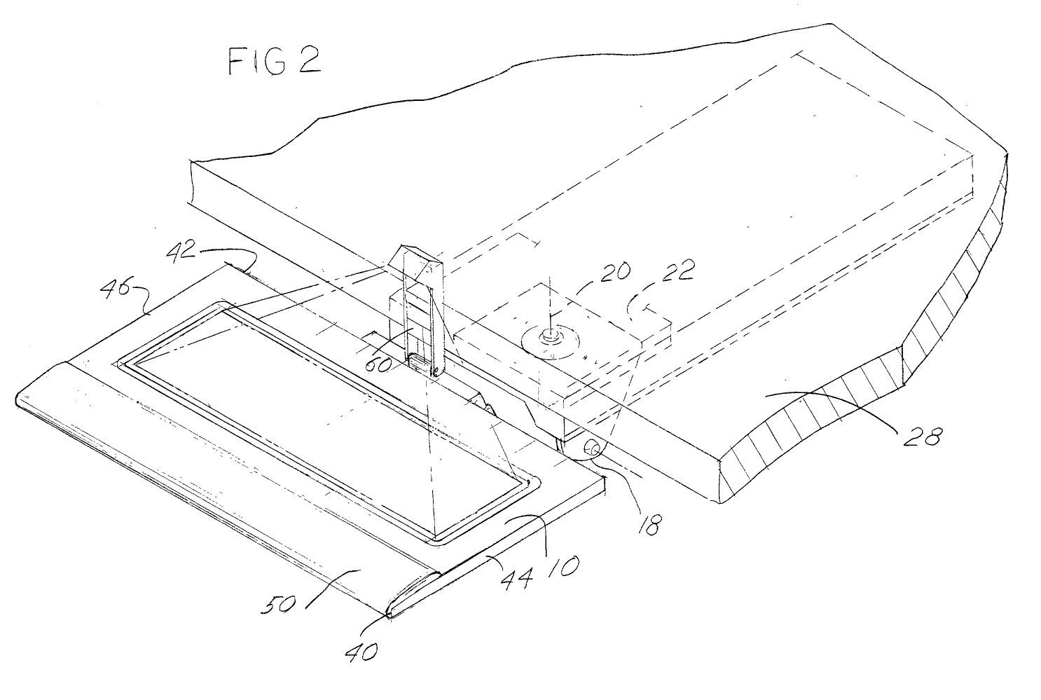

### DESCRIPTION OF THE PREFERRED EMBODIMENT

Referring to the figures, a flat planar keyboard support platform 10 includes an undercarriage comprising a mounting bracket 12 attached to the platform 10. Pivotally connected to the bracket 10 about pivot axes 11, 13 are first and second linkage arms 14 and 16. The arms 14 and 16 are, in turn, pivotally attached at separate pivot points 15, 17 to an undercarriage bracket 18. The undercarriage bracket 18 is pivotal about a vertical axis 20. The bracket 18 is thus attached to a sliding plate 22 which slides in channels 24 and 26 on the underside of a desk support surface 28.

The platform 10 may be raised and lowered and adjusted in any of a number of ways by virtue of the connecting mechanism between the platform 10 and the desk surface 28. Thus, the platform 10 may be moved inwardly and outwardly as a result of the mounting of the plate 22 in the sliding channels 26 and 27. The bracket 18 may be pivoted about the vertical pivot axis 20. The arms 14 and 16 which are pivotally connected to brackets 12 and 18, respectively, again may be pivoted to raise and lower the platform 10. The pitch of the platform, in other words, the tilt thereof may be adjusted by virtue of a mechanism connecting the platform 10 to the bracket 12. The yaw or roll of the platform 10 may also be adjusted by a mechanism associated with the bracket 12.

Numerous patents illustrate various alternative constructions for attaching a platform 10 to a work surface 28 and those patents listed in the Background of the Invention are incorporated herewith by reference.

Importantly, the platform 10 comprises a general flat, planar image receiving surface having a bottom or lower edge 40 and upper or top edge 42, a first side edge 44 and a second spaced, side edge 46. In this preferred embodiment the platform 10 includes a generally flat planar surface 48. The platform 10 further includes a wrist rest pad 50 along the front edge 40. The platform 10 is desirably perfectly planar and includes a projector 60 mounted at top edge 42. The projector 60 is a virtual image projector and projects an image outwardly and downwardly onto the flat surface 48 as depicted in the drawing. The preferred projection comprises a standard keyboard alone or in combination with a key pad operated mouse control 62. The planar surface 10 thus comprises a keyboard which may actuate, for example, a personal computer or a computer via a connection of the sensory equipment associated with the projector 60. Projectors and sensors of the type described are available through Siemens of Hanover, Germany or directly through VKV, Inc. if Israel, the disclosure and description of which is incorporated herewith by reference.

Importantly the platform 48 is a flat and even texture throughout so that the projection from the projector 60 will be uniform and complete. However, alternative surface treatments, colors, textures, and the like may be utilized in the practice of the invention. For example, a projection of red or blue images upon a colored background may be provided to reduce eye strain and other physical strain that is associated with extended periods of typing. Further, by permitting adjustment and then fixing of the platform 10 in space relative to the desk 28, an ergonomic benefit can be achieved. An ergonomic benefit can be enhanced by utilization of proper pads such as pad 50 for support of the wrist. Positioning of the projector 60 along the top edge 42 ensures that the orientation position, size, and use of the input image projected on the platform will be useful.

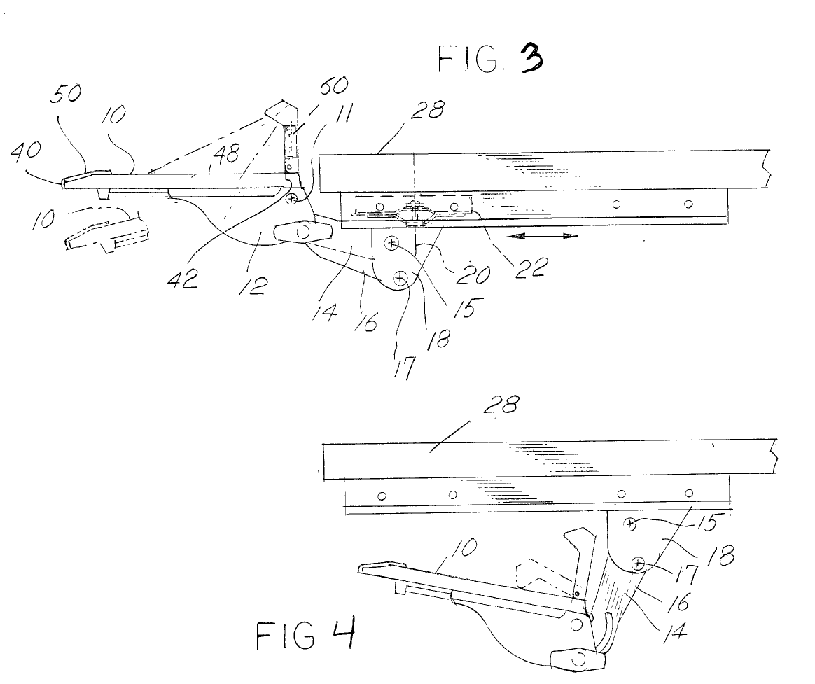

The surface of the keyboard 10 may also be coated with an elastic or shock absorbing material to reduce finger strain such as a layer of foam rubber (11 in FIG. 3). As a further alternative, the keyboard 10 may support a flexible cloth or fabric keyboard such as made by Logitech. Placement of a hook and loop fastening mechanism (Velcro fastener) on the under surface of a fabric pad, 13 in FIG. 4, will facilitate placement and retention of the fabric keyboard device on the keyboard 10. In such a circumstance, the fabric pad 13 is utilized in conjunction with a pilot sized processor rather than a projector 60.

It is possible to vary the construction of the support assembly to otherwise accommodate the flat, planar platform which preferably is monochromatic but which may be multicolored and may be patterned, for example, to coincide with the projection of the projector 50. In this manner a fail-safe mechanism may be provided in that, so long as the projection image is substantially identical to the preset image on the platform surface.

What is claimed is:

1. A virtual keyboard and keyboard support arm assembly comprising, in combination:
a keyboard platform having a generally flat planar projection surface with a top edge, a bottom edge and spaced first and second, opposite side edges defining an image projection plane;
a bracket assembly for said support platform for attachment of the platform to a desk support, said bracket assembly including means for adjusting one or more of the level, pitch, and yaw of the platform and the extent of spacing of the platform from the desk support; and
a virtual projection monitor mounted on the keyboard platform at the top edge for projecting a virtual keyboard image onto the projection surface and for sensing the site specific interaction of digital placement on the virtual image.

2. The combination of claim 1 wherein the virtual keyboard image includes sight specific locations for computer control.

3. The combination of claim 1 wherein the bracket assembly further includes a brake mechanism for maintaining the support platform in a specific orientation and position.

4. The combination of claim 1 wherein the bracket assembly includes an arm having a first end connected to the platform and a second end connected to a desk support and further wherein the connection at each end of the arm is adjustable.

5. The combination of claim 1 wherein two or more arms connect the keyboard platform to a desk support and wherein the connections are pivotal to effect alterations in orientation and height of the support platform relative to the desk support.

6. The combination of claim 1 wherein the platform further includes at least one support pad located thereon for ergonomic support of a person utilizing the virtual keyboard image to input signals to a processor.

7. The combination of claim 1 wherein the keyboard platform may be locked in a fixed position in space and with a fixed orientation relative to the desk support and further wherein the pitch, yaw, level and spacing of the platform are each independently adjustable.
